(19) United States
(12) Patent Application Publication
(10) Pub. No.: US 2025/0261457 A1
(43) Pub. Date: Aug. 14, 2025

(54) 3D STACKED APD/SPAD FOR VISIBLE LIGHT OPERATING AT HIGH SPEED

(71) Applicant: SHENZHEN ADAPS PHOTONICS TECHNOLOGY CO., LTD., Shenzhen (CN)

(72) Inventors: Ching-Ying LU, Shenzhen (CN); Yangsen Kang, San Jose, CA (US); Shuang Li, Shenzhen (CN)

(21) Appl. No.: 19/053,128

(22) Filed: Feb. 13, 2025

Related U.S. Application Data
(60) Provisional application No. 63/553,039, filed on Feb. 13, 2024.

(51) Int. Cl. H10F 39/12; H10F 39/00; H10F 39/10

(52) U.S. Cl. CPC H10F 39/199; H10F 39/103; H10F 39/8063; H10F 39/807; H10F 39/809; H10F 39/811

(57) ABSTRACT

In an embodiment, the present disclosure provides a backside illumination (BSI) photodiode device comprising a backside with a plurality of microlenses coupled to it, including a first microlens and a second microlens. The device includes a first doped region of p-type material within a first thickness of the backside, and a first sidewall with a first deep trench isolation (DTI) region. A frontside comprises a first sub-pixel region aligned against the first microlens and a second sub-pixel region aligned against the second microlens, each containing shaped p-type and n-type layers. An interconnect layer includes electrodes coupled to the shaped layers. The device may further include an application specific integrated circuit (ASIC) coupled to the electrodes, and can function as an avalanche photodiode or single photon avalanche diode with a thickness less than 3 um between the frontside and backside. There are other embodiments as well.

### CROSS-REFERENCES TO RELATED APPLICATIONS

The present application claims priority to U.S. Provisional Application No. 63/553,039, entitled “3D STACKED APD/SPAD FOR VISIBLE LIGHT OPERATING AT HIGH SPEED”, filed Feb. 13, 2024, which is common own and incorporated by reference herein for all purposes.

### BACKGROUND OF THE INVENTION

The present disclosure relates to photodetector devices, and more particularly to a high-speed backside-illuminated avalanche photodiode or single-photon avalanche diode with a 3D stacked architecture.

In recent years, the exponential growth of artificial intelligence (AI) and machine learning (ML) technologies has dramatically increased the demand for high-speed data processing and real-time communication within data centers. AI-driven applications, such as deep learning, natural language processing, and autonomous systems, need vast amounts of data to be processed in parallel across distributed computing networks. This surge in data volume and complexity has pushed the limits of traditional electrical interconnects used in data centers, leading to the widespread adoption of optical communication technologies to meet the need for higher bandwidth, lower latency, and energy-efficient data transmission.

In AI data centers, optical transceivers serve as the backbone for high-speed data exchange between servers, storage units, and computational nodes. These transceivers rely on photodiodes, such as avalanche photodiodes (APDs) and single-photon avalanche diodes (SPADs), to detect optical signals and convert them into electrical signals that can be processed by digital systems. However, as AI models grow larger and more complex, the speed at which these photodiodes can read out and process incoming optical signals becomes a critical performance factor.

Therefore, new and improved photodiode devices are desired.

### BRIEF SUMMARY OF THE INVENTION

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

In an embodiment, the present disclosure provides a backside illumination photodiode device comprising a backside with a plurality of microlenses coupled to it, including a first microlens and a second microlens. The device includes a first doped region of p-type material within a first thickness of the backside, and a first sidewall with a first deep trench isolation region. A frontside comprises a first sub-pixel region aligned against the first microlens and a second sub-pixel region aligned against the second microlens, each containing shaped p-type and n-type layers. An interconnect layer includes electrodes coupled to the shaped layers. The device may further include an application specific integrated circuit coupled to the electrodes, and can function as an avalanche photodiode or single photon avalanche diode with a thickness less than 3 um between the frontside and backside. There are other embodiments as well.

According to an aspect of the present disclosure, a backside illumination (BSI) photodiode device is provided. The device includes a backside and a plurality of microlenses coupled to the backside, the plurality of microlenses comprising a first microlens and a second microlens. The device includes a first doped region configured within a first thickness of the backside, the first doped region comprising a p-type material. The device includes a first sidewall and a second sidewall, the first sidewall comprising a first deep trench isolation (DTI) region. The device includes a frontside. The device includes a first sub-pixel region positioned with a second thickness of the frontside and aligned against the first microlens, the first sub-pixel region comprising a first shaped p-type layer and a first shaped n-type layer. The device includes a second sub-pixel region positioned with the second thickness of the frontside and aligned against the second microlens, the second sub-pixel region comprising a second shaped p-type layer and a second shaped n-type layer. The device includes an interconnect layer comprising a first plurality of electrodes and a second plurality of electrodes, the first plurality of electrodes being coupled to the first shaped p-type layer and the second shaped p-type layer, and the second plurality of electrodes being coupled to the first shaped n-type layer and the second shaped n-type layer.

According to other aspects of the present disclosure, the device may include one or more of the following features. The device may include a third shaped n-type layer positioned between the first sub-pixel region and the second sub-pixel region. The device may include an application specific integrated circuit (ASIC) coupled to the first plurality of electrodes and the second plurality of electrodes. The first plurality of electrodes may comprise a plurality of anodes, and the second plurality of electrodes may comprise a plurality of cathodes. The BSI photodiode device may comprise an avalanche photodiode or a single photon avalanche diode. The first sub-pixel region and the second sub-pixel region may be separated by a shallow trench isolation region. The device may include an epitaxial layer positioned between the backside and the frontside. The device may include a first side layer positioned along the first sidewall, the first side layer comprising the p-type material. The device may include a second side layer positioned along the first side layer, the second side layer comprising the p-type material and characterized by a doping gradient, a first side of the second side layer interfacing the first side layer being characterized by a higher doping concentration compared to a second side of the second side layer positioned away from the first side layer. A thickness between the frontside and the backside may be less than 3 um.

According to another aspect of the present disclosure, a backside illumination (BSI) photodiode device is provided. The device includes a backside and a plurality of microlenses coupled to the backside. The device includes a first doped region comprising a p-type material positioned within a first thickness of the backside. The device includes a frontside opposite the backside. The device includes a first sub-pixel region and a second sub-pixel region positioned on the frontside, each comprising a shaped p-type layer and a shaped n-type layer, the first sub-pixel region being aligned against a first microlens. The device includes an interconnect layer comprising a plurality of electrodes coupled to the shaped p-type layers and the shaped n-type layers. The device includes an application-specific integrated circuit (ASIC) coupled to the plurality of electrodes, the ASIC configured to process electrical signals generated by the sub-pixel regions for high-speed readout.

According to other aspects of the present disclosure, the device may include one or more of the following features. The shaped p-type layer and the shaped n-type layer in each sub-pixel region may be separated by a shallow trench isolation (STI) region. The device may include a deep trench isolation (DTI) region separating adjacent sub-pixel regions. The first doped region may extend along sidewalls of the device, forming a continuous p-type layer around the sub-pixel regions. The device may include a gradient doped p-type layer adjacent to the first doped region, the gradient doped p-type layer having a higher doping concentration near the first doped region and a lower doping concentration away from the first doped region. The shaped n-type layer in each sub-pixel region may comprise multiple finger electrodes to reduce lateral transit time.

According to an aspect of the present disclosure, an optical receiver system is provided. The system includes a plurality of photodiodes configured according to a first arrangement, which is based on a second arrangement associated with a bundle of optical communication links. Each photodiode in the plurality may include a backside and a frontside, with a first doped p-type region within a first thickness of the backside. The photodiode may have sidewalls, with at least one sidewall comprising a deep trench isolation (DTI) region. The frontside may include multiple sub-pixel regions, each comprising shaped p-type and n-type layers. An interconnect layer with electrodes may couple to these shaped layers.

In some aspects, the system may include a microlens aligned with a sub-pixel region of a photodiode. The interconnect layer may comprise anodes coupled to p-type layers and cathodes coupled to n-type layers. In certain implementations, a photodiode in the system may be characterized by a width ranging from 40 μm to 60 μm.

The optical receiver system may be configured to receive and process optical signals from multiple communication links, with its photodiode arrangement corresponding to the arrangement of these links. This configuration may allow for efficient detection and processing of optical signals in high-speed communication applications.

The present invention achieves these benefits and others in the context of known technology. However, a further understanding of the nature and advantages of the present invention may be realized by reference to the latter portions of the specification and attached drawings.

### BRIEF DESCRIPTION OF THE DRAWINGS

Non-limiting and non-exhaustive examples are described with reference to the following figures.

FIG. 1A illustrates a cross-sectional view of a BSI photodiode, according to aspects of the present disclosure.

FIG. 1B illustrates a top view of a BSI photodiode with a 2×2 sub-pixel array configuration, according to an embodiment.

FIG. 2 illustrates a cross-sectional view of a BSI photodiode with gradient doping layers, according to aspects of the present disclosure.

FIG. 3 illustrates a top orthogonal view of a sub-pixel array, according to an embodiment.

FIG. 4 illustrates a top orthogonal view of a pixel array, according to aspects of the present disclosure.

FIG. 5A illustrates a cross-sectional view of a photodiode, according to an embodiment.

FIG. 5B illustrates a top view of the photodiode of FIG. 5A, according to aspects of the present disclosure.

### DETAILED DESCRIPTION OF THE INVENTION

In an embodiment, the present disclosure provides a backside illumination photodiode device comprising a backside with a plurality of microlenses coupled to it, including a first microlens and a second microlens. The device includes a first doped region of p-type material within a first thickness of the backside, and a first sidewall with a first deep trench isolation region. A frontside comprises a first sub-pixel region aligned against the first microlens and a second sub-pixel region aligned against the second microlens, each containing shaped p-type and n-type layers. An interconnect layer includes electrodes coupled to the shaped layers. The device may further include an application specific integrated circuit coupled to the electrodes, and can function as an avalanche photodiode or single photon avalanche diode with a thickness less than 3 um between the frontside and backside. There are other embodiments as well.

As mentioned above, existing photodiode devices are inadequate for optical communication applications. For example, existing frontside-illuminated (FSI) photodiode architectures face several limitations that hinder their performance in high-speed applications. In FSI structures, incoming photons must pass through multiple dielectric layers and metal interconnects before reaching the active region of the photodiode, resulting in optical losses and longer carrier transit times. This not only reduces the sensitivity of the device but also introduces latency that limits the achievable data rates.

To address these issues, backside illumination (BSI) architectures have been developed, wherein photons directly enter the active region of the photodiode from the backside of the device. This configuration minimizes optical losses and enables more efficient photon absorption. However, even with BSI designs, challenges remain in optimizing readout speed and signal integrity, particularly when scaling photodiode arrays for high-bandwidth applications.

A challenge in achieving high-speed readout is the carrier transit time—the time it takes for photo-generated carriers (electrons and holes) to reach the collection electrodes. In conventional photodiodes, carrier transit time is often dominated by diffusion processes, which are inherently slower and introduce variability in signal timing. This becomes a bottleneck in applications requiring precise timing resolution, such as time-of-flight (ToF) sensors and photon-counting communication systems.

To overcome these limitations, APDs and SPADs are employed, in various embodiments, due to their ability to operate in avalanche mode, where a single photon can trigger a cascade of charge carriers through impact ionization. This process significantly amplifies the signal, enabling detection of even extremely weak optical signals. However, the readout circuitry must be capable of handling these rapid signal events with minimal delay and noise, which is often challenging with conventional integrated circuit (IC) technologies.

Various implementations of the present invention utilize 3D stacking technology have opened new possibilities for integrating high-speed application-specific integrated circuits (ASICs) directly with photodiode arrays. By stacking the ASIC on a separate wafer from the photodiode sensor, designers can leverage advanced semiconductor process nodes (e.g., 20 nm for ASICs and 40 nm+ for photodiodes) to optimize both speed and sensitivity. This approach allows for parallel processing of signals from multiple photodiode elements, significantly reducing latency and power consumption while improving data throughput.

In various embodiments, the present invention provides innovations such as multiple pn-junction regions, gradient doping profiles, and deep trench isolation (DTI) techniques have been introduced to enhance the performance of APDs and SPADs. These features reduce lateral carrier transit times, minimize crosstalk between adjacent pixels, and improve overall signal-to-noise ratios (SNR). Combined with backside microlens arrays that focus light precisely onto the active regions of the photodiode, these technologies enable faster, more accurate detection and readout of optical signals.

It is to be appreciated that photodiode architectures according to embodiments of the present invention that can deliver ultra-fast readout speeds while maintaining high sensitivity and low noise characteristics. Such devices are critical for next-generation high-speed communication systems, where the ability to transmit and process large volumes of data with minimal delay and high fidelity is paramount.

The following description is presented to enable one of ordinary skill in the art to make and use the invention and to incorporate it in the context of particular applications. Various modifications, as well as a variety of uses in different applications will be readily apparent to those skilled in the art, and the general principles defined herein may be applied to a wide range of embodiments. Thus, the present invention is not intended to be limited to the embodiments presented, but is to be accorded the widest scope consistent with the principles and novel features disclosed herein.

In the following detailed description, numerous specific details are set forth in order to provide a more thorough understanding of the present invention. However, it will be apparent to one skilled in the art that the present invention may be practiced without necessarily being limited to these specific details. In other instances, well-known structures and devices are shown in block diagram form, rather than in detail, in order to avoid obscuring the present invention.

The reader's attention is directed to all papers and documents which are filed concurrently with this specification and which are open to public inspection with this specification, and the contents of all such papers and documents are incorporated herein by reference. All the features disclosed in this specification, (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the Claims herein is not intended to invoke the provisions of 35 U.S.C. 112, Paragraph 6.

Please note, if used, the labels left, right, front, back, top, bottom, forward, reverse, clockwise and counter clockwise have been used for convenience purposes only and are not intended to imply any particular fixed direction. Instead, they are used to reflect relative locations and/or directions between various portions of an object.

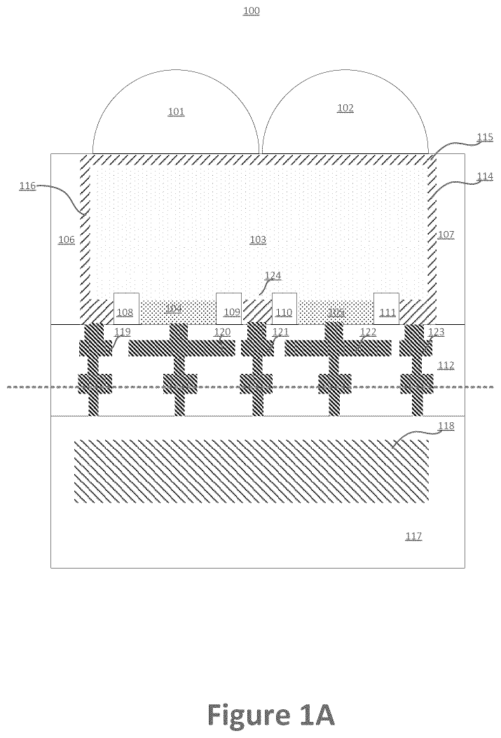

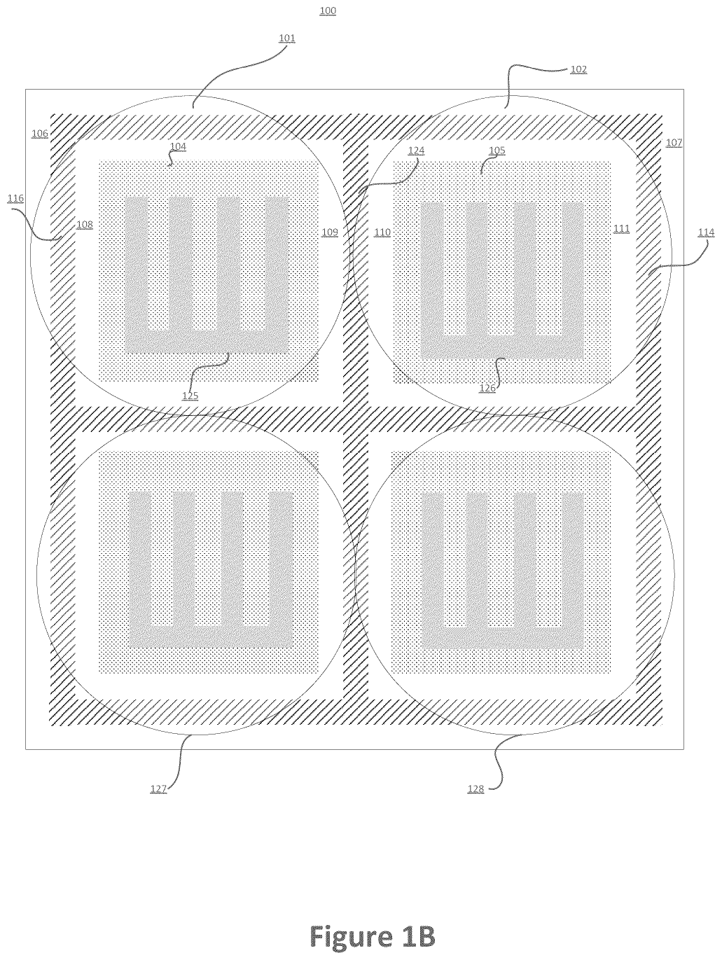

FIG. 1A illustrates a cross-sectional view of a BSI photodiode 100. The BSI photodiode 100 may include a backside and a frontside. This diagram is merely an example, which should not unduly limit the scope of the claims. One of ordinary skill in the art would recognize many variations, alternatives, and modifications. In some cases, a plurality of microlenses may be coupled to the backside of the BSI photodiode 100. The plurality of microlenses may include a microlens 101 and a microlens 102. These microlenses may be configured to focus incident light onto the active regions of the device.

The BSI photodiode 100 may include an epitaxial layer 103 positioned between the backside and the frontside. Within the epitaxial layer 103, a first sub-pixel region and a second sub-pixel region may be positioned with a thickness of the frontside. The first sub-pixel region may be aligned against the microlens 101 and may comprise a shaped n-type layer 104. The second sub-pixel region may be aligned against the microlens 102 and may comprise a shaped n-type layer 105.

In some cases, the BSI photodiode 100 may include a first doped region configured within a thickness of the backside. This first doped region may comprise a p-type material and may include a p-type top layer 115. The device may also include p-type side layers 114, 116, and 124 positioned along the sides of the structure.

The BSI photodiode 100 may include a first sidewall and a second sidewall. In some implementations, the first sidewall may comprise a DTI 106, and the second sidewall may comprise a DTI 107. These deep trench isolation regions may provide electrical isolation between adjacent pixels or sub-pixels.

Within the sub-pixel regions, shallow trench isolation (STI) structures may be present. These may include STI 108, STI 109, STI 110, and STI 111. The STI structures may provide isolation between different doped regions within each sub-pixel.

An interconnect layer 112 may be included in the BSI photodiode 100. This interconnect layer 112 may comprise a first plurality of electrodes and a second plurality of electrodes. In some cases, the first plurality of electrodes may include anodes 119, 121, and 123, while the second plurality of electrodes may include cathodes 120 and 122. The first plurality of electrodes may be coupled to the shaped p-type layers, and the second plurality of electrodes may be coupled to the shaped n-type layers.

The BSI photodiode 100 may be configured in a 3D stacked structure. In this configuration, an ASIC substrate 117 may be positioned below the interconnect layer 112. An ASIC 118 may be fabricated on the ASIC substrate 117. The ASIC 118 may be coupled to the first plurality of electrodes and the second plurality of electrodes through the interconnect layer 112.

In some implementations, the thickness between the frontside and the backside of the BSI photodiode 100 may be less than 3 μm. This thin structure may contribute to the high-speed operation of the device.

The BSI photodiode 100 may be configured as an avalanche photodiode or a single photon avalanche diode. These configurations may allow for high sensitivity in low-light conditions and may enable single-photon detection in some cases.

In some implementations of the BSI photodiode 100 shown in FIG. 1A, large pixels (e.g., those exceeding 15 μm in size) may be divided into smaller sub-pixel regions to enhance device performance. For example, a large pixel may be divided into a 2×2, 3×3, or 4×4 array of sub-pixels. This sub-pixel division, as illustrated by the first sub-pixel region containing shaped n-type layer 104 and the second sub-pixel region containing shaped n-type layer 105, may help reduce lateral transit time for charge carriers, potentially increasing the overall speed of the device.

The sub-pixel regions within a larger pixel may be designed with uniform or non-uniform sizes and shapes. This flexibility in sub-pixel configuration may allow for optimization of the device for specific applications or light detection requirements. In some cases, non-uniform sub-pixel arrangements may be used to enhance sensitivity in particular areas of the pixel or to match expected light distribution patterns.

To further improve light collection efficiency, the BSI photodiode 100 may employ multiple microlenses for each pixel. For instance, a 2×2, 3×3, or 4×4 array of microlenses, such as microlenses 101 and 102, may be used to focus incident light onto high-field regions within the sub-pixels. This microlens array configuration may help concentrate light onto the most sensitive areas of each sub-pixel, potentially improving overall quantum efficiency and signal-to-noise ratio.

The BSI photodiode 100 may also incorporate backside deep trench isolation (DTI) structures, such as DTI 106 and DTI 107, between pixels to reduce crosstalk. These DTI structures may extend from the backside of the device towards the frontside, creating physical and electrical barriers between adjacent pixels. By minimizing the spread of charge carriers between neighboring pixels, the DTI structures may help maintain signal integrity and improve overall image quality, particularly in high-contrast scenes or when detecting fine details.

FIG. 1B illustrates a top view of the BSI photodiode 100 with a 2×2 sub-pixel array configuration. This diagram is merely an example, which should not unduly limit the scope of the claims. One of ordinary skill in the art would recognize many variations, alternatives, and modifications. The BSI photodiode 100 includes four sub-pixels arranged in a square pattern, each having similar internal structures.

The structure includes the microlenses 101 and 102, as well as a microlens 127 and a microlens 128 positioned at each corner of the array. These microlenses may be configured to focus incident light onto their respective sub-pixels.

The deep trench isolation (DTI) structures 106 and 107 form the outer boundaries of the array, providing electrical isolation between adjacent pixels. Within each sub-pixel, the shallow trench isolation (STI) structures 108, 109, 110, and 111 are arranged in parallel strips. These STI structures may separate different doped regions within each sub-pixel.

The array includes p-type regions with a p-type side layer 114 and a p-type side layer 116, as well as the p-type top layer 115. A shaped p-type layer 125 and a shaped p-type layer 126 are incorporated into the structure. The epitaxial layer 103 forms part of the device structure, along with the shaped n-type layers 104 and 105.

In some cases, the BSI photodiode 100 may include a third shaped n-type layer positioned between the first sub-pixel region and the second sub-pixel region. This third shaped n-type layer may provide additional control over the electrical characteristics of the device.

The arrangement of the components creates four distinct sub-pixels, each containing multiple parallel structures separated by the STI regions. In some cases, the first sub-pixel region and the second sub-pixel region may be separated by a shallow trench isolation region. This separation may help reduce electrical crosstalk between adjacent sub-pixels.

In some implementations of the BSI photodiode 100 shown in FIG. 1A, the device may be optimized for visible light detection in the range of approximately 380-700 nanometers. The epitaxial layer 103 may be designed to be relatively thin, as silicon has a high absorption coefficient in this wavelength range. This thin epitaxial structure may allow for efficient absorption of visible light photons within a compact device architecture. The backside illumination configuration of the BSI photodiode 100 may offer several advantages over traditional frontside illuminated structures. In frontside illuminated devices, incident light typically must pass through thick dielectric layers before reaching the active region, potentially resulting in undesired absorption and reduced sensitivity. However, in the BSI photodiode 100, light enters directly from the backside where no thick dielectric layers are present. This design choice may significantly increase the device's sensitivity to incoming light.

The 3D stacked structure of the BSI photodiode 100, with the ASIC 118 positioned on a separate substrate 117, may allow for a larger absorption region in the sensor portion without compromising area for the ASIC 118. This separation of the sensor and ASIC components may enable more efficient use of the device's overall footprint. Additionally, the stacked configuration may help reduce sensor blockage that might occur if the ASIC were positioned in the light path. By placing the ASIC 118 below the sensor portion, the BSI photodiode 100 may achieve improved light collection efficiency and overall performance.

It is to be appreciated that in the BSI photodiode 100 of FIG. 1A, the absence of a thick silicon substrate may contribute to reduced thermal noise. The thin epitaxial layer 103 may minimize the volume of silicon in which thermally generated carriers can be produced. This reduction in thermally generated carriers may lead to improved signal-to-noise ratio (SNR), particularly in low-light conditions where thermal noise can be a significant factor.

When configured as a single-photon avalanche diode (SPAD), the BSI photodiode 100 may experience thermal noise in the form of dark counts. These are false detection events caused by thermally generated carriers triggering avalanche events. The thin structure of the BSI photodiode 100 may help minimize the dark count rate by reducing the volume in which thermal carriers can be generated, potentially improving the device's SNR and detection accuracy. The BSI photodiode 100 lacks a thick substrate typically found in frontside illuminated sensors. This absence may allow for a shorter carrier transit distance from the backside to the collection regions near the frontside. The reduced transit distance may decrease the probability of carrier recombination or trapping, potentially leading to improved quantum efficiency and SNR, especially for longer wavelengths of light that penetrate deeper into silicon. The thin structure of the BSI photodiode 100 may allow for a reduced depletion region compared to traditional thick sensors. This smaller depletion region may result in lower capacitance, potentially enabling faster response times and reduced electronic noise. The combination of lower capacitance and reduced noise may contribute to an improved SNR, particularly in high-speed applications where rapid signal readout is critical.

In various implementations, the BSI photodiode 100 features an optimized structure for backside illumination. The arrangement of the p-type top layer 115 and the shaped n-type layers 104 and 105 may create an electric field profile that efficiently directs photo-generated carriers towards the collection regions. This optimized structure may enhance charge collection efficiency and reduce lateral diffusion of carriers, potentially improving the device's SNR by minimizing crosstalk between adjacent sub-pixels and increasing the overall quantum efficiency of the sensor.

While FIG. 1B illustrates a 2×2 sub-pixel array configuration, in some cases, the sub-pixel array may be arranged in other configurations such as 3×3 or 4×4. These different configurations may allow for flexibility in designing the BSI photodiode 100 for various applications and performance requirements.

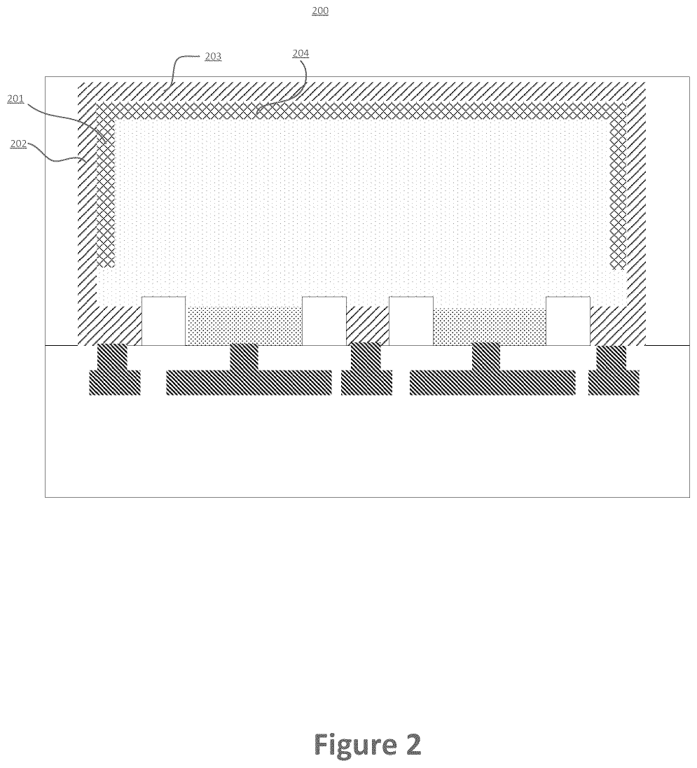

FIG. 2 illustrates a cross-sectional view of a BSI photodiode 200. This diagram is merely an example, which should not unduly limit the scope of the claims. One of ordinary skill in the art would recognize many variations, alternatives, and modifications. The BSI photodiode 200 may include multiple p-type layers arranged in a configuration that creates a gradient doping profile.

In some cases, the BSI photodiode 200 may include a p-type gradient side layer 201 positioned along the side of the structure. A p-type side layer 202 may be adjacent to the p-type gradient side layer 201. The p-type side layer 202 may comprise a p-type material and may be positioned along a first sidewall of the BSI photodiode 200.

The top portion of the structure may comprise a p-type top layer 203 and a p-type gradient top layer 204. The p-type gradient side layer 201 and the p-type gradient top layer 204 may be implemented to create an electric field that can accelerate carriers within the device.

In some implementations, the p-type gradient side layer 201 may be characterized by a doping gradient. A first side of the p-type gradient side layer 201 interfacing the p-type side layer 202 may be characterized by a higher doping concentration compared to a second side of the p-type gradient side layer 201 positioned away from the p-type side layer 202. This gradient doping profile may contribute to improved carrier acceleration and device performance.

The arrangement of these p-type layers with varying doping concentrations may create a built-in electric field within the BSI photodiode 200. This electric field may help to accelerate photo-generated carriers towards the collection regions, potentially improving the speed and efficiency of the device.

In some cases, the gradient doping profile may extend from the side regions to the top regions of the BSI photodiode 200, creating a continuous gradient effect. This configuration may help to optimize carrier collection across different areas of the device.

In some implementations of the BSI photodiode 200 shown in FIG. 2, multiple implant regions may be incorporated to create a doping gradient within the device structure. This gradient doping profile is illustrated by the p-type gradient side layer 201 and the p-type gradient top layer 204, which are positioned adjacent to the p-type side layer 202 and p-type top layer 203, respectively. The doping gradient created by these multiple implant regions may generate an electric field within the device. This electric field may serve to accelerate charge carriers (electrons and holes) as they move through the structure. For example, the gradient between the p-type gradient side layer 201 and the p-type side layer 202 may create an electric field that directs carriers laterally, while the gradient between the p-type gradient top layer 204 and other regions may create a vertical electric field component. The acceleration of carriers due to these electric fields may result in faster transit times for photo-generated charges moving towards collection regions. This reduction in transit time may lead to faster readout of the optical signal, potentially enabling higher speed operation of the BSI photodiode 200.

In some cases, the specific doping profiles and gradients may be tailored to optimize carrier acceleration for particular wavelengths of light or specific application requirements. The ability to fine-tune these doping gradients may provide a means to balance factors such as sensitivity, speed, and noise performance in the BSI photodiode 200.

The cross-sectional view shows the internal arrangement of these p-type layers, which form part of the photodiode structure. The bottom portion of the figure may show additional structural elements including isolation regions and interconnect features, which may be similar to those described in relation to other figures.

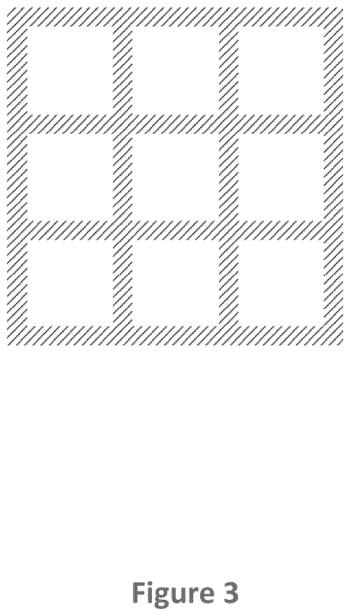

FIG. 3 illustrates a top orthogonal view of a sub-pixel array 300. The sub-pixel array 300 may be arranged in a 3×3 grid pattern, where each cell in the grid represents an individual sub-pixel. In some cases, the sub-pixels may be separated by hatched boundary regions that define the borders between adjacent sub-pixels.

The array structure of the sub-pixel array 300 may show nine equally-sized square sub-pixels arranged in a uniform pattern. The hatched regions surrounding and separating the sub-pixels may indicate isolation structures between the individual sub-pixels. These isolation structures may be similar to the deep trench isolation (DTI) or shallow trench isolation (STI) structures described in relation to other figures.

In some implementations, the sub-pixel array 300 may be part of a larger BSI photodiode structure. Each sub-pixel within the array may include components such as shaped n-type layers, shaped p-type layers, and other elements described in relation to previous figures.

The 3×3 grid pattern of the sub-pixel array 300 may offer several advantages for device performance and functionality. In some cases, this arrangement may allow for improved spatial resolution in light detection. By dividing a larger pixel into multiple sub-pixels, the device may be able to capture more detailed information about the distribution of incident light.

The isolation structures between sub-pixels, as indicated by the hatched regions, may help reduce electrical crosstalk between adjacent sub-pixels. This reduction in crosstalk may contribute to improved signal integrity and may allow for more accurate light detection and measurement.

In some implementations, the 3×3 grid pattern may also facilitate parallel readout of multiple sub-pixels. This parallel readout capability may contribute to faster overall device operation, potentially enabling high-speed applications such as time-of-flight measurements or high-frame-rate imaging.

The uniform size and arrangement of the sub-pixels in the sub-pixel array 300 may allow for consistent performance across the array. In some cases, this uniformity may simplify signal processing and calibration procedures for the overall device.

In some implementations, the sub-pixel array 300 shown in FIG. 3 may be part of a stacked structure that allows for highly flexible pixel arrangements. This flexibility in pixel array patterns may enable the sensor detection region to better match the optical profile of various objects or phenomena being detected, potentially leading to enhanced sensitivity.

The 3×3 grid pattern illustrated in FIG. 3 is just one possible configuration. In other implementations, the sub-pixel array may be arranged in non-uniform patterns or other shapes to suit specific detection requirements. For example, the array may be configured in circular, hexagonal, or irregular patterns depending on the application needs. This adaptability in pixel arrangement may make the device suitable for a wide range of applications. In some cases, the pixel layout may be optimized to match the expected light distribution of a particular scene or object, potentially improving overall detection efficiency. The ability to customize the pixel array pattern may allow for tailored solutions in various fields such as machine vision, automotive sensing, or scientific imaging. The flexibility afforded by the stacked structure may also enable the integration of pixels with different sizes or sensitivities within the same array. This heterogeneous pixel arrangement may, in some implementations, allow for simultaneous capture of high-resolution details and high-sensitivity low-light information, further expanding the device's potential applications.

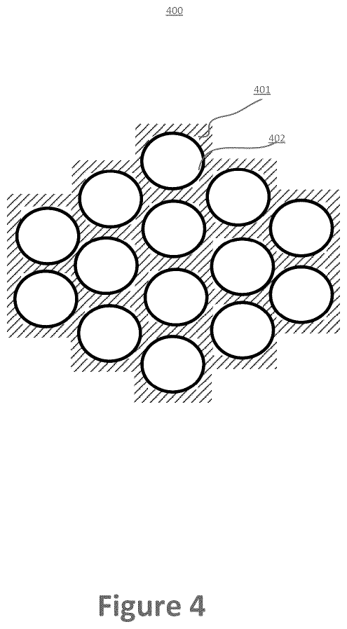

FIG. 4 illustrates a top orthogonal view of a pixel array 400. The pixel array 400 may comprise multiple square-shaped pixels arranged in a non-uniform pattern. In some cases, the pixels in the pixel array 400 may be represented by hatched squares that are positioned in an asymmetric configuration.

The arrangement of the pixel array 400 may show varying spacing between individual pixels, creating an irregular grid pattern. In some implementations, the pixels in the pixel array 400 may be distributed across the array in a manner that allows for flexible positioning while maintaining connectivity between the elements.

This non-uniform arrangement of pixels in the pixel array 400 may provide several potential advantages for various applications. In some cases, the flexible configuration may allow for customization of the pixel layout to match specific light detection requirements. For example, certain regions of the pixel array 400 may have a higher density of pixels to provide increased resolution in areas of interest.

In some cases, the pixel array 400 may be part of a larger BSI photodiode structure. Each pixel within the array may include components such as shaped n-type layers, shaped p-type layers, and other elements described in relation to previous figures.

The pixel array 400 may also offer advantages in terms of signal processing and readout. In some cases, the non-uniform arrangement may allow for selective readout of specific regions of interest within the array, potentially enabling faster processing for certain applications.

While FIG. 4 illustrates a specific non-uniform arrangement, in some implementations, the pixel array 400 may be configured with different patterns or distributions of pixels. The specific configuration may be chosen based on factors such as desired spatial resolution, readout speed, or application-specific requirements.

As an example, the pixel array 400 comprises multiple circular pixels arranged in a hexagonal pattern. Pixel array 400 includes pixel 401 and an optical link 402 aligned to the first pixel 401. For example, the space between pixels is represented by a hatched pattern, indicating isolation structures or boundaries between individual pixels, which may include deep trench isolation (DTI) regions. Depending on the implementation, pixel array may include hundred or more pixels that are arranged to align to a bundle of optical links (e.g., fiber optics), where one or more pixels may be configured to detect light from an optical link.

It is to be appreciated that the 2D array structure facilitates easy scaling to accommodate additional channels. This allows for increased optical communication capacity within a compact footprint, making it suitable for high-density optical receiver applications. The array can be easily scaled to match the arrangement of bundled optical communication links.

In some embodiments, some sub-pixels within the array may serve as matched dummy capacitors in the differential circuit. This enhances circuit balance and symmetry, improving overall performance. The configuration optimizes the power supply rejection ratio (PSRR) and common-mode rejection ratio (CMRR) of the differential circuit. By providing closely matched capacitive elements within the same array structure, the design reduces sensitivity to power supply fluctuations and common-mode noise. In various embodiments, the pixel arrangement contributes to improved noise performance through the balanced distribution of sub-pixels and the ability to implement differential sensing techniques.

The pixel arrangement allows for next-generation devices where the fiber pitch can be reduced from the current 50 μm to 25 μm. This 2D array sensor can be easily scaled to achieve 4× bandwidth in future implementations, demonstrating its adaptability to evolving optical communication standards.

The system may include microlenses aligned with sub-pixel regions, enhancing light collection efficiency and potentially improving signal-to-noise ratio. The photodiodes in the array can be designed with specific dimensions, such as a width of 40 μm to 60 μm, to match the requirements of various optical communication systems and fiber pitches. The interconnect layer comprises a plurality of anodes coupled to the p-type layers and a plurality of cathodes coupled to the n-type layers, facilitating efficient signal collection and routing.

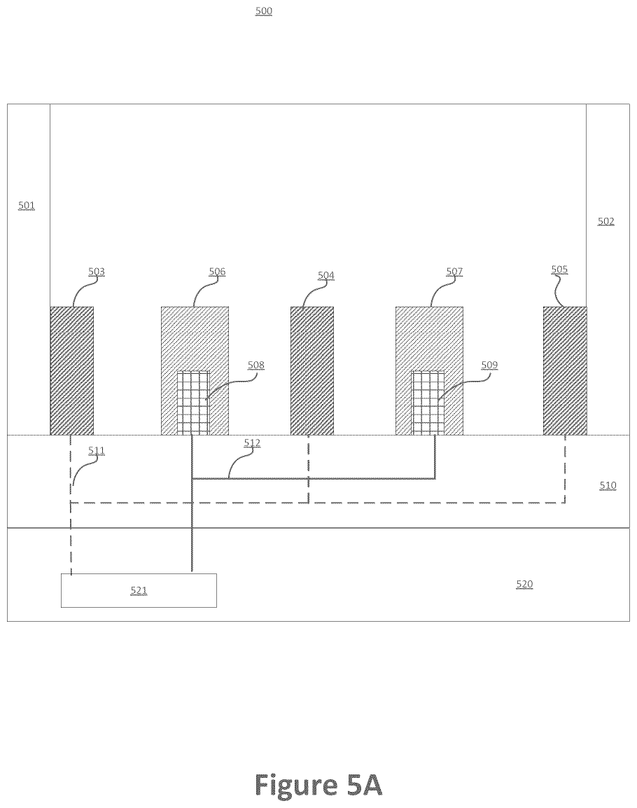

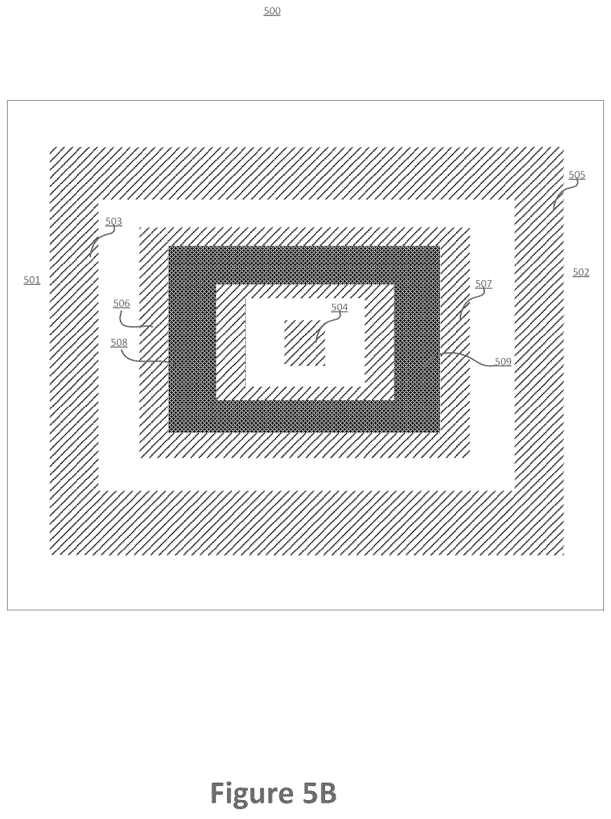

FIG. 5A illustrates a cross-sectional view of a photodiode 500. The photodiode 500 may include a first sidewall 501 and a second sidewall 502 defining the lateral boundaries of the device. In some cases, the photodiode 500 may be configured as a BSI photodiode.

The photodiode 500 may comprise multiple p-type layers arranged within the structure. These may include a p-type layer 503, a p-type layer 504, a p-type layer 505, a p-type layer 506, and a p-type layer 507. The p-type layers may be positioned at different locations across the device width, contributing to the overall electrical characteristics of the photodiode 500. Depending on the implementation, p-type layers may be characterized with different doping concentrations.

In some implementations, the photodiode 500 may incorporate n-type layers 508 and 509. These n-type layers may be positioned within the device and may have a grid-like pattern. In some cases, the n-type layers 508 and 509 may comprise multiple finger electrodes. The finger electrode configuration may help reduce lateral transit time for charge carriers, potentially improving the speed of the device.

An interconnect layer 510 may be located at the bottom portion of the photodiode 500. The interconnect layer 510 may connect to various components including an anode 511 and a cathode 512. These electrodes may facilitate the collection and transmission of electrical signals generated within the photodiode 500.

The bottom section of the photodiode 500 may include a substrate 520. In some cases, an ASIC 521 may be fabricated on the substrate 520. The ASIC 521 may be coupled to the anode 511 and cathode 512 through the interconnect layer 510. This configuration may allow the ASIC 521 to process electrical signals generated by the photodiode 500 for high-speed readout.

In some implementations, the ASIC 521 may be fabricated using a more advanced technology node compared to the photodiode 500. For example, the ASIC 521 may be manufactured using a 20 nm process, while the photodiode 500 may be fabricated using a 40 nm or larger process. This difference in manufacturing processes may allow for optimization of both the sensing capabilities of the photodiode 500 and the processing speed of the ASIC 521.

The p-type layers and n-type layers may be arranged in an alternating pattern, creating distinct regions within the photodiode 500 structure. This arrangement may contribute to the formation of sub-pixel regions within the device. In some cases, the shaped n-type layers in each sub-pixel region may comprise multiple finger electrodes to reduce lateral transit time for charge carriers.

In some implementations of the photodiode device 500 shown in FIG. 5B, the concentric p-type layers may be separated from each other by specific distances to optimize device performance. For example, the distance between adjacent concentric p-type layers, such as between p-type layer 503 and p-type layer 504, or between p-type layer 504 and p-type layer 505, may be in the range of 2 micrometers (μm) to 5 μm. This spacing may help balance various factors such as charge collection efficiency, crosstalk reduction between adjacent regions, and overall device sensitivity. The separation distance between adjacent p-type layers may be selected based on factors including the intended application of the photodiode, the desired spectral response, and the specific manufacturing process used. In some cases, a separation distance within the 2 μm to 5 μm range may allow for efficient charge carrier collection while maintaining a compact overall device structure. This spacing may also facilitate the formation of depletion regions between adjacent p-type layers, which may contribute to improved photodetection performance. It should be noted that while a range of 2 μm to 5 μm is described, the actual separation distance may vary depending on specific design requirements and may be adjusted within or even outside this range in some implementations. The ability to fine-tune these separation distances may provide flexibility in optimizing the photodiode device for various applications, such as high-speed imaging, low-light detection, or specific wavelength sensitivity.

The cross-sectional view shows the vertical arrangement of these components, with the interconnect layer 510 providing electrical connections between the photodiode 500 structure and the ASIC 521. This configuration may enable efficient signal processing and high-speed readout of the electrical signals generated by the sub-pixel regions of the photodiode 500.

FIG. 5B illustrates a top orthogonal view of the photodiode 500. This diagram is merely an example, which should not unduly limit the scope of the claims. One of ordinary skill in the art would recognize many variations, alternatives, and modifications. The photodiode 500 may include the first sidewall 501 and the second sidewall 502 that define the outer boundaries of the device. In some cases, the structure may comprise multiple concentric regions with different doping characteristics.

The photodiode 500 may include several p-type layers arranged in a concentric pattern. The p-type layer 503 may be positioned near the first sidewall 501, while the p-type layer 504 may form an inner region. Additional p-type layers including the p-type layer 505, the p-type layer 506, and the p-type layer 507 may be arranged in a pattern moving outward from the center.

In some implementations, the structure may also incorporate n-type regions. A n-type layer 508 may be positioned adjacent to the p-type layer 506, and a n-type layer 509 may be located near the second sidewall 502. The arrangement of these doped regions may create a series of alternating p-type and n-type regions across the device.

The concentric pattern of the doped regions may be indicated by different hatching patterns in the figure. In some cases, diagonal lines may represent certain regions while darker shading may indicate others. This arrangement of doped layers may enable the photodiode 500 to function as a light-sensing device.

In some implementations, the concentric arrangement of p-type and n-type layers may contribute to the overall light-sensing capabilities of the photodiode 500. The alternating pattern of differently doped regions may create multiple p-n junctions within the device. These junctions may facilitate the separation and collection of photo-generated charge carriers.

The concentric configuration may allow for efficient light absorption across the entire area of the photodiode 500. In some cases, this arrangement may help to minimize edge effects and ensure uniform sensitivity across the device. The multiple concentric regions may also contribute to improved charge collection efficiency, as carriers generated in different areas of the device may have shorter distances to travel to reach collection regions.

In some implementations, the n-type layers 508 and 509 may serve as cathode regions, while the p-type layers may function as anode regions. The alternating arrangement of these layers may create a radial electric field within the photodiode 500. This radial field may help to guide photo-generated carriers towards the collection regions, potentially improving the speed and efficiency of the device.

The concentric configuration may also offer advantages in terms of device scalability. In some cases, the number and width of the concentric regions may be adjusted to optimize the photodiode 500 for specific applications or performance requirements. This flexibility may allow for customization of the device's characteristics such as sensitivity, speed, or spectral response.

This diagram is merely an example, which should not unduly limit the scope of the claims. One of ordinary skill in the art would recognize many variations, alternatives, and modifications.

While the above is a full description of the specific embodiments, various modifications, alternative constructions and equivalents may be used. Therefore, the above description and illustrations should not be taken as limiting the scope of the present invention which is defined by the appended claims.

What is claimed is:

1. A backside illumination (BSI) photodiode device comprising:
a backside;
a plurality of microlenses coupled to the backside, the plurality of microlenses comprising a first microlens and a second microlens;
a first doped region configured within a first thickness of the backside, the first doped region comprising a p-type material;
a first sidewall and a second sidewall, the first sidewall comprising a first deep trench isolation (DTI) region;
a frontside;
a first sub-pixel region positioned with a second thickness of the frontside and aligned against the first microlens, the first sub-pixel region comprising a first shaped p-type layer and a first shaped n-type layer;
a second sub-pixel region positioned with the second thickness of the frontside and aligned against the second microlens, the second sub-pixel region comprising a second shaped p-type layer and a second shaped n-type layer; and
an interconnect layer comprising a first plurality of electrodes and a second plurality of electrodes, the first plurality of electrodes being coupled to the first shaped p-type layer and the second shaped p-type layer, and the second plurality of electrodes being coupled to the first shaped n-type layer and the second shaped n-type layer.

2. The device of claim 1, further comprising a third shaped n-type layer positioned between the first sub-pixel region and the second sub-pixel region.

3. The device of claim 1, further comprising an application specific integrated circuit (ASIC) coupled to the first plurality of electrodes and the second plurality of electrodes.

4. The device of claim 1, wherein the first plurality of electrodes comprises a plurality of anodes, and the second plurality of electrodes comprises a plurality of cathodes.

5. The device of claim 1, wherein the BSI photodiode device comprises an avalanche photodiode or a single photon avalanche diode.

6. The device of claim 1, wherein the first sub-pixel region and the second sub-pixel region are separated by a shallow trench isolation region.

7. The device of claim 1, further comprising an epitaxial layer positioned between the backside and the frontside.

8. The device of claim 1, further comprising a first side layer positioned along the first sidewall, the first side layer comprising the p-type material.

9. The device of claim 1, further comprising a second side layer positioned along the first side layer, the second side layer comprising the p-type material and characterized by a doping gradient, a first side of the second side layer interfacing the first side layer being characterized by a higher doping concentration compared to a second side of the second side layer positioned away from the first side layer.

10. The device of claim 1, wherein a thickness between the frontside and the backside is less than 3 um.

11. A backside illumination (BSI) photodiode device comprising:
a backside;
a plurality of microlenses coupled to the backside;
a first doped region comprising a p-type material positioned within a first thickness of the backside;
a frontside opposite the backside;
a first sub-pixel region and a second sub-pixel region positioned on the frontside, each comprising a shaped p-type layer and a shaped n-type layer;
an interconnect layer comprising a plurality of electrodes coupled to the shaped p-type layers and the shaped n-type layers; and
an application-specific integrated circuit (ASIC) coupled to the plurality of electrodes, the ASIC configured to process electrical signals generated by the sub-pixel regions for high-speed readout.

12. The device of claim 11, wherein the shaped p-type layer and the shaped n-type layer in each sub-pixel region are separated by a shallow trench isolation (STI) region.

13. The device of claim 11, wherein the first doped region extends along sidewalls of the device, forming a continuous p-type layer around the sub-pixel regions.

14. The device of claim 11, wherein the shaped n-type layer in each sub-pixel region comprises multiple finger electrodes to reduce lateral transit time.

15. The device of claim 11, further comprising a gradient doped p-type layer adjacent to the first doped region, the gradient doped p-type layer having a higher doping concentration near the first doped region and a lower doping concentration away from the first doped region.

16. An optical receiver system comprising;
a plurality of photodiodes configured according to a first arrangement, the first arrangement being based a second arrangement associated with a bundle optical communication links, the plurality of photodiodes comprising a first photodiode, the first photodiode comprising:
a backside;
a first doped region configured within a first thickness of the backside, the first doped region comprising a p-type material;
a first sidewall and a second sidewall, the first sidewall comprising a first deep trench isolation (DTI) region;
a frontside;
a first sub-pixel region positioned with a second thickness of the frontside, the first sub-pixel region comprising a first shaped p-type layer and a first shaped n-type layer;
a second sub-pixel region positioned with the second thickness of the frontside, the second sub-pixel region comprising a second shaped p-type layer and a second shaped n-type layer; and
an interconnect layer comprising a first plurality of electrodes and a second plurality of electrodes, the first plurality of electrodes being coupled to the first shaped p-type layer and the second shaped p-type layer, and the second plurality of electrodes being coupled to the first shaped n-type layer and the second shaped n-type layer.

17. The system of claim 16, further comprising a first microlens aligned against the first sub-pixel.

18. The system of claim 16, wherein the interconnect layer comprises a plurality of anodes coupled to the p-type layers and a plurality of cathodes coupled to the n-type layers.

19. The system of claim 16, wherein the first photodiode is characterized by a width of 40 um to 60 um.
